(19) United States
(12) Patent Application Publication
(10) Pub. No.: US 2024/0113106 A1
(43) Pub. Date: Apr. 4, 2024

(54) ETCH STOP LAYER FOR METAL GATE CUT

(71) Applicant: Intel Corporation, Santa Clara, CA (US)

(72) Inventors: Sukru Yemenicioglu, Portland, OR (US); Nikhil J. Mehta, Portland, OR (US); Leonard P. Guler, Hillsboro, OR (US); Daniel J. Harris, Beaverton, OR (US)

(73) Assignee: Intel Corporation, Santa Clara, CA (US)

(21) Appl. No.: 17/957,106

(22) Filed: Sep. 30, 2022

(51) Int. Cl. H01L 27/088; H01L 21/8234

(52) U.S. Cl. CPC H01L 27/088; H01L 21/823456; H01L 21/823481

(57) ABSTRACT

An integrated circuit includes laterally adjacent first and second devices. The first device includes (i) first source and drain regions, (ii) a first body including semiconductor material laterally extending between the first source and drain regions, (iii) a first sub-fin below the first body, and (iv) a first gate structure on the first body. The second device includes (i) second source and drain regions, (ii) a second body including semiconductor material laterally extending from the second source and drain regions, (iii) a second sub-fin below the second body, and (iv) a second gate structure on the second body. A second dielectric material is laterally between the first and second sub-fins. A third dielectric material is laterally between the first and second sub-fins, and above the second dielectric material. A gate cut including first dielectric material is laterally between the first and second gate structures, and above the third dielectric material.

### FIELD OF THE DISCLOSURE

The present disclosure relates to integrated circuits, and more particularly, to transistor devices having gate cuts.

### BACKGROUND

As integrated circuits continue to scale downward in size, a number of challenges arise. For instance, reducing the size of memory and logic cells is becoming increasingly more difficult, as is reducing inter-device spacing at the device layer. A gate cut structure comprising dielectric material isolates gate structures of two adjacent transistor devices, and is formed between the two adjacent transistor devices. As transistors are packed more densely, the formation of certain device structures used to isolate adjacent transistors (such as a gate cut structure) becomes challenging. Accordingly, there remain a number of non-trivial challenges with respect to forming semiconductor devices.

### BRIEF DESCRIPTION OF THE DRAWINGS

FIGS. 1A and 1B illustrate cross-sectional views of an integrated circuit structure comprising semiconductor devices, wherein a first dielectric material is between sub-fins of adjacent devices, wherein a second dielectric material is above the first dielectric material, wherein a gate cut between gate structures of two respective devices extends at least in part within the second dielectric material, and wherein the second dielectric material acts as an etch stop layer during formation of a trench for the gate cut, according to an embodiment of the present disclosure.

FIG. 2 illustrates a cross-sectional view of another integrated circuit structure that is at least in part similar to the integrated circuit structure of FIGS. 1A-1B, wherein a gate cut between two devices in the structure of FIG. 2 extends fully within and through the second dielectric material, and is in contact with the first dielectric material, according to an embodiment of the present disclosure.

FIG. 3A illustrates a cross-sectional view of another integrated circuit structure that is at least in part similar to the integrated circuit structures of FIGS. 1A-1B, wherein a substrate has been planarized and polished off at least in part (or fully) from the backside of the structure of FIG. 3A, according to an embodiment of the present disclosure.

FIG. 3B illustrates the integrated circuit structure of FIG. 3A, with a frontside interconnect structure above and a backside interconnect structure below the integrated circuit structure of FIG. 3B, according to an embodiment of the present disclosure.

FIG. 3C illustrates a cross-sectional view of another integrated circuit structure that is at least in part similar to the integrated circuit structures of FIGS. 1A-1B, wherein the substrate and the first dielectric material has been polished off at least in part (or fully) from the backside of the structure of FIG. 3C, according to an embodiment of the present disclosure.

FIG. 3D illustrates the integrated circuit structure of FIG. 3C, with a frontside interconnect structure above and a backside interconnect structure below the integrated circuit structure of FIG. 3C, according to an embodiment of the present disclosure.

FIG. 4 illustrates a flowchart depicting a method of forming the integrated circuit structures of FIGS. 1A-3D, in accordance with an embodiment of the present disclosure.

FIGS. 5A, 5B, 5C, 5D, 5E, 5F, 5G, 5H, 5I, 5J, and 5K collectively illustrate cross-sectional views of an integrated circuit structure in various stages of processing in accordance with the methodology of FIG. 4, in accordance with an embodiment of the present disclosure.

FIG. 6 illustrates a computing system implemented with integrated circuit structures (such as the integrated circuit structures illustrated in FIGS. 1A-3) formed using the techniques disclosed herein, in accordance with some embodiments of the present disclosure.

As will be appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used. Likewise, while the thickness of a given first layer may appear to be similar in thickness to a second layer, in actuality that first layer may be much thinner or thicker than the second layer; same goes for other layer or feature dimensions.

### DETAILED DESCRIPTION

Techniques are provided herein to form semiconductor devices that include one or more gate cuts laterally between two corresponding adjacent gate structures, and wherein the gate cuts land on or within an etch stop layer or in some cases pass through the etch stop layer. The etch stop layer allows for the gate cuts to have a relatively uniform height (e.g., within 10 nm of one another, or within 5 nm of each other), relative to a configuration where there is no underlying etch stop and the gate cut heights can vary greatly (e.g., gate cut height variance of over 20 nm). More generally, the etch stop operates to stop or to otherwise slow down the gate cut trench etch so as to effectively dampen the variation in any punch-through etch. For example, the etch stop layer comprises dielectric material and is laterally between two corresponding adjacent sub-fins. The etch stop layer stops or dampens etch processes used to form trenches for the gate cuts. Accordingly, the gate cut trenches may not reach or extend past the sub-fin bottoms and into an underlying substrate, as the gate cut trenches may be stopped by the etch stop layer, or otherwise more uniformly pass there-trough and to a lesser extent. For instance, in some such example cases, the trenches land on the etch stop or within the etch stop. In other such example cases, the trenches pass-through the etch stop but only extend into the underlying dielectric material layer by no more than a threshold distance of 10 nm or 20 nm and in a relatively uniform fashion, or otherwise do not extend past the sub-fin bottoms and into an underlying substrate. In an example, the substrate (or at least a part thereof) may be polished and removed from the backside, such as the example case where the backside polish generally stops at the bottom surface of the trough between fins so as to define the sub-fin bottom surfaces. In a standard process, any gate cut trenches extending too deep into the substrate can make the backside polishing process of the substrate difficult. However, the etch stop layer described herein stops the gate cut trenches from reaching the backside portion of the substrate to be removed, thereby avoiding any such difficulty in the backside polishing process. The techniques can be used in any number of integrated circuit applications and are particularly useful with respect to device layer transistors, such as finFETs or gate-all-around (GAA) transistors (e.g., where the channel regions comprise nanoribbons, nanowires).

In one embodiment, an integrated circuit comprises laterally adjacent first and second semiconductor devices. The first semiconductor device comprises (i) a first source region, (ii) a first drain region, (iii) a first body comprising semiconductor material extending in a first direction from the first source region to the first drain region, (iv) a first sub-fin below the first body, and (v) a first gate structure extending in a second direction and on the first body. The second semiconductor device comprises (i) a second source region, (ii) a second drain region, (iii) a second body comprising semiconductor material extending in the first direction from the second source region to the second drain region, (iv) a second sub-fin below the second body, and (v) a second gate structure extending in the second direction and on the second body. A gate cut is laterally between and separates the first gate structure and the second gate structure, the gate cut comprising a first dielectric material. A second dielectric material is laterally between the first and second sub-fins, and a third dielectric material is (i) laterally between the first and second sub-fins and (i) above the second dielectric material. In an example, the gate cut is above the third dielectric material, and the third dielectric material is an etch stop layer that stops an etch process for forming a recess or trench for the gate cut.

In another embodiment, an integrated circuit comprises a first sub-fin, and a first gate structure above the first sub-fin. The integrated circuit further comprises a second sub-fin, and a second gate structure above the second sub-fin. A gate cut is laterally between the first and second gate structures, the gate cut comprising a first dielectric material. A second dielectric material is laterally between the first and second sub-fins. In an example, an etch stop layer is between the second dielectric material and the gate cut. In an example, the etch stop layer stops an etch process for forming a recess or trench for the gate cut.

In yet another embodiment, an integrated circuit comprises a first sub-fin, and a first gate structure above the first sub-fin, a second sub-fin, and a second gate structure above the second sub-fin. A structure is laterally between and separates the first and second gate structures, the structure comprising a first dielectric material. A second dielectric material is laterally between the first and second sub-fins, and the structure lands on the second dielectric material. A backside interconnect structure comprises a third dielectric material and is below the first and second sub-fins. The second dielectric material is compositionally distinct from the first dielectric material and the third dielectric material.

Numerous configurations and variations will be apparent in light of this disclosure.

### GENERAL OVERVIEW

As previously noted above, there remain a number of non-trivial challenges with respect to integrated circuit fabrication. In more detail, when forming a trench for a gate cut through a gate structure, the etch process may not only form the trench though the common gate structure, but also into the underlying the substrate. Thus, in an example where multiple gate cuts are implemented in an integrated circuit structure, depending on the widths of the various gate cuts, the gate cut trenches may extend at various depths within the underlying substrate, with some trenches extending much deeper than others. Unfortunately, the gate cut trenches that extend too deep within the substrate make it difficult to polish the substrate from the backside of the wafer (the gate cut materials are interfere with the polish process).

Thus, and in accordance with an embodiment of the present disclosure, techniques are provided herein to use an etch stop layer above the substrate, where the etch stop layer stops or otherwise dampens the etch process during formation of the gate cut trenches, thereby preventing the gate cut trenches from reaching deep into the underlying substrate. Thus, as the gate cut trenches now do not extend deep into within the substrate, the above described difficulties in backside polishing of the substrate can be avoided. The techniques are useful in forming any number of gate cut structures, including gate cut structures having a relatively high height-to-width aspect ratio (e.g., 5:1 or higher, such as 8:1, or 10:1). The etch stop effectively operates to reduce the adverse impact of loading effects during high aspect ratio etching processes used to form the gate cut trenches.

In an example, a first semiconductor device has a first channel region (e.g., comprising one or more nanoribbons, one or more nanowires, one or more nanosheets, or a fin) extending laterally between a first source region and a first drain region, and a first gate structure on the first channel region, where the first channel region is formed above a first sub-fin. Similarly, a second semiconductor device has a second channel region extending laterally between a second source region and a second drain region, and a second gate structure on the second channel region, where the second channel region is formed above a second sub-fin. In an example, a gate cut is laterally between the first gate structure and the second gate structure, where the gate cut comprises a first dielectric material.

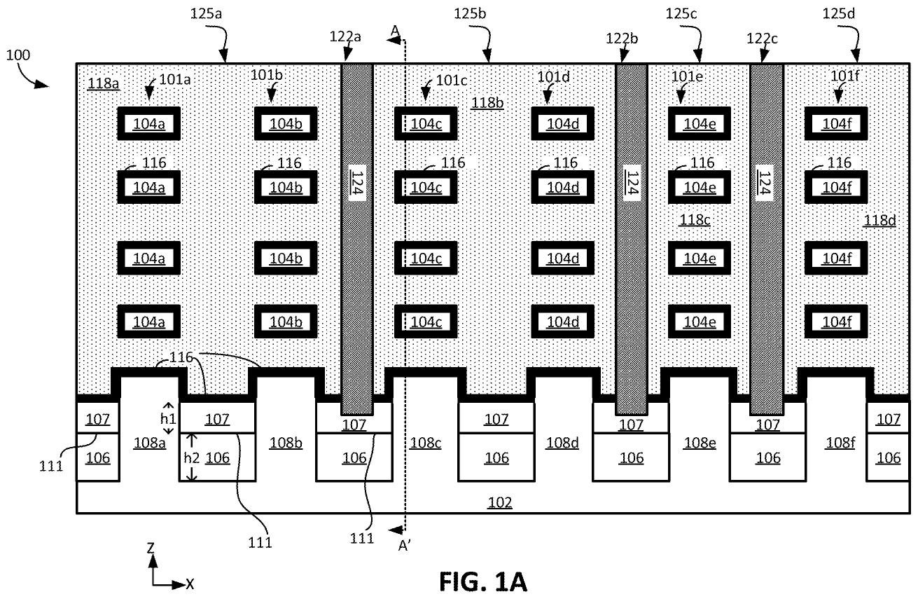

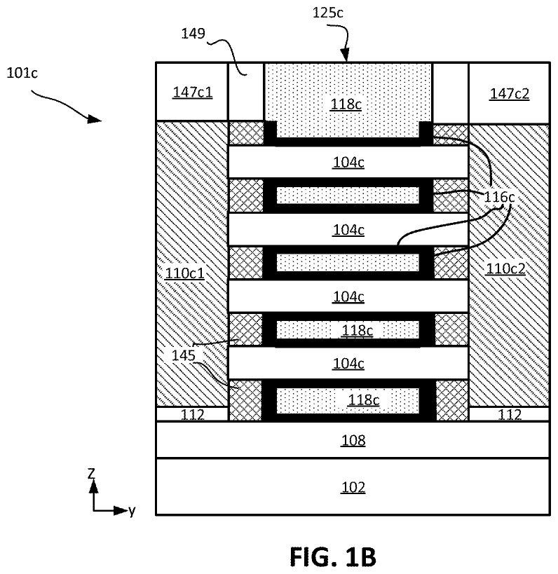

During formation of the integrated circuit structure including the first and second devices, the first and second devices may initially be over a substrate, although the substrate can be later at least in part removed by way of backside polishing. In an example, a second dielectric material (e.g., dielectric material 106 of FIG. 1A) may be between the first and second sub-fins and above the substrate (although as discussed, the substrate may be later removed in some examples), and a third dielectric material (e.g., dielectric material 107 of FIG. 1A) may be between the first and second sub-fins and above the second dielectric material. In an example, the third dielectric material acts as an etch stop layer, which stops the etch process for formation of the gate cut trench. Thus, the gate cut is above the third dielectric material. In an example, the gate cut may extend in part within the third dielectric material, but may not extend through (e.g., may not punch through) the third dielectric material. Accordingly, the gate cut trench does not reach or extend within the second dielectric material, and also does not reach or extend within the substrate. Hence, a backside polishing process, to remove part of or the entire substrate, does not face the above described difficulties.

In an example, the second and third dielectric materials may be elementally and/or compositionally different, although they may be elementally same in another example. Examples of the third dielectric material acting as the etch stop layer include silicon nitride (SiN), silicon oxynitride (SiON), silicon carbide (SiC), silicon oxycarbide (SiOC), silicon oxycarbonitride (SiOCN), or silicon oxide (SiO), for example. In some such example cases, the second dielectric material includes an oxide and the third dielectric material includes a nitride, or vice-versa. In some other such example cases, the second dielectric material includes an oxide and the third dielectric material includes a carbide, or vice-versa. In still other such example cases, the second dielectric material includes an nitride and the third dielectric material includes a carbide, or vice-versa.

In an example, during the formation process of the integrated circuit, the second and third dielectric materials may be deposited between adjacent sub-fin regions, e.g., after formation of the fins, and before the formation of the dummy or sacrificial gate process. In an example, after deposition of the second and third dielectric materials, a common dummy gate is formed for the above described first and second devices, followed by formation of the inner gate spacers and source and drain regions of the first and second devices. The dummy gate is then removed and the nanoribbons (or other GAA channel regions, such as nanowires or nanosheets) are released, and a common replacement gate structure is formed on the channel regions of the first and second devices. Subsequently, the gate cut trench is formed within the common gate structure, to divide the common gate structure into a first gate structure for the first device and a second gate structure for the second device.

The etch process for formation of the gate cut is stopped by the third dielectric material, which acts as the etch stop layer. Accordingly, the gate cut trench stops at the third dielectric material, and does not reach the second dielectric material or the substrate. The gate cut trench is then filled with dielectric material, to form the gate cut. The substrate is then optionally polished from the backside, to removed part of, or the entirety, of the substrate. As described, because the gate cut trench does not reach the substrate, the above described difficulties in the backside polishing process is eliminated.

The use of “group IV semiconductor material” (or “group IV material” or generally, “IV”) herein includes at least one group IV element (e.g., silicon, germanium, carbon, tin), such as silicon (Si), germanium (Ge), silicon-germanium (SiGe), and so forth. The use of “group III-V semiconductor material” (or “group III-V material” or generally, “III-V”) herein includes at least one group III element (e.g., aluminum, gallium, indium) and at least one group V element (e.g., nitrogen, phosphorus, arsenic, antimony, bismuth), such as gallium arsenide (GaAs), indium gallium arsenide (InGaAs), indium aluminum arsenide (InAlAs), gallium phosphide (GaP), gallium antimonide (GaSb), indium phosphide (InP), gallium nitride (GaN), and so forth. Note that group III may also be known as the boron group or IUPAC group 13, group IV may also be known as the carbon group or IUPAC group 14, and group V may also be known as the nitrogen family or IUPAC group 15, for example.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For example, in some embodiments, such tools may be used to detect (i) a first device comprising a first sub-fin and a first gate structure above the first sub-fin, (ii) a second device comprising a second sub-fin and a second gate structure above the second sub-fin, (iii) a gate cut comprising a first dielectric material laterally between the first and second gate structures, (iv) a second dielectric material laterally between the first and second sub-fins, where the gate cut structure extends within, and not through, the second dielectric material, and (v) a third dielectric material laterally between the first and second sub-fins and below the second dielectric material. In an example, the second dielectric material is an etch stop layer that stops an etch process for forming a recess or trench for the gate cut. Numerous configurations and variations will be apparent in light of this disclosure.

Architecture

FIGS. 1A and 1B illustrate cross-sectional views of an integrated circuit structure 100 comprising semiconductor devices 101a, 101b, 101c, 101d, 101e, and 101f, wherein a first dielectric material 106 is between sub-fins 108 of adjacent devices, wherein a second dielectric material 107 is above the first dielectric material 106, wherein a gate cut 122a between gate structures 125a, 125b of the respective devices 101b and 101c extends at least in part within the second dielectric material 107, and wherein the second dielectric material 107 acts as an etch stop layer during formation of a trench for the gate cut 122a, according to an embodiment of the present disclosure.

The cross-sectional view of FIG. 1A is taken across the gate structure of the semiconductor devices, and illustrates cross-sectional views of the channel regions 104. The cross-sectional view of FIG. 1B is along a line A-A′ of FIG. 1A that passes through the device 101c, and only the device 101c is illustrated in the cross-sectional view of FIG. 1B. Note that the gut cuts 122 are not visible in the cross-sectional view of FIG. 1B.

In an example, each of semiconductor devices 101a, . . . , 101f may be non-planar metal oxide semiconductor (MOS) transistors, such as tri-gate (e.g., finFET) or gate-all-around (GAA) transistors, although other transistor topologies and types could also benefit from the techniques provided herein. The illustrated embodiments herein use the GAA structure including nanoribbons as channel regions. The term nanoribbon may also encompass other similar GAA channel region shapes such as nanowires or nanosheets. Note that the nanoribbons of a device may be replaced by a fin-based structured in one example, to form a finFET device.

The various illustrated semiconductor devices represent a portion of an integrated circuit that may contain any number of similar semiconductor devices. Thus, although six example devices are illustrated, there may be additional devices. For example, although FIG. 1A illustrates the devices 101c and 101d being adjacent, there may be one or more other devices between the devices 101c and 101d.

Each of devices 101a, . . . , 101f includes corresponding one or more nanoribbons 104a, . . . , 104f, respectively, that extend parallel to one another along a Y-axis direction of FIG. 1B (e.g., a first direction into and out of the page in the cross-section view of FIG. 1A), between corresponding source and drain regions 110. The source and drain regions 110 are illustrated in FIG. 1B. Nanoribbons 104 are one example of semiconductor regions or semiconductor bodies that extend between source and drain regions 110. The semiconductor material of nanoribbons 104 may be formed from substrate 102, in an example. In some embodiments, devices 101a, . . . , 101f may each include semiconductor regions in the shape of fins that can be, for example, native to substrate 102 (formed from the substrate itself), such as silicon (Si) fins etched from a bulk silicon substrate. Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of the illustrated nanoribbons 104 during a gate forming process where one type of the alternating layers is selectively etched away so as to liberate the other type of alternating layers within the channel region, so that a gate-all-around (GAA) process can then be carried out. Again, the alternating layers can be blanket deposited and then etched into fins or deposited into fin-shaped trenches. In an example, the nanoribbons 104 comprise an appropriate semiconductor material, such as silicon (Si), silicon germanium (SiGe), or another appropriate semiconductor material.

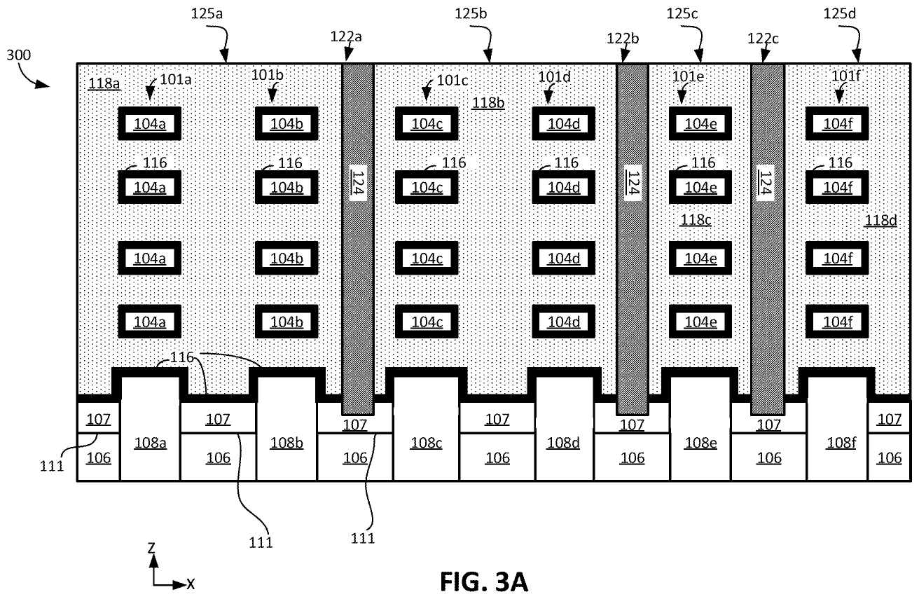

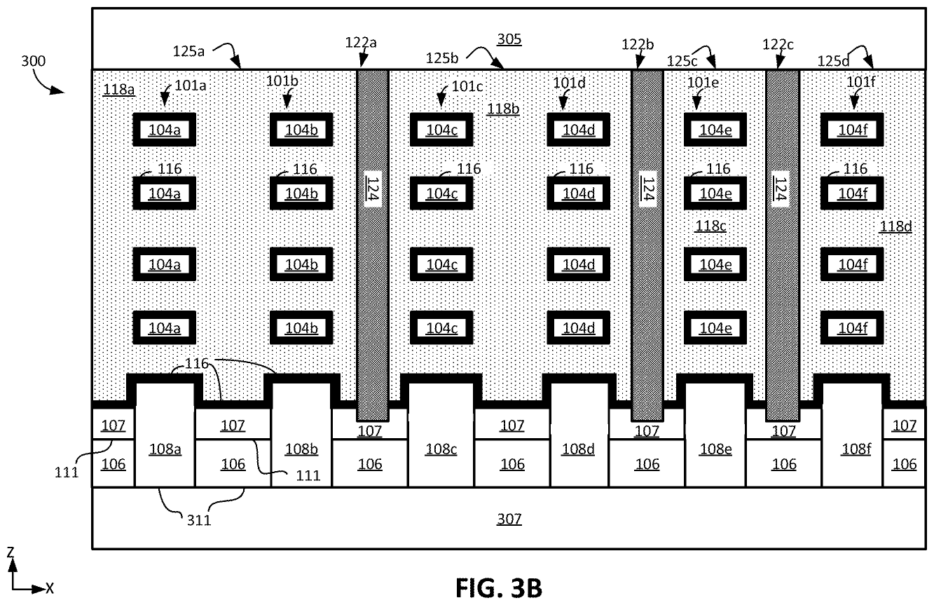

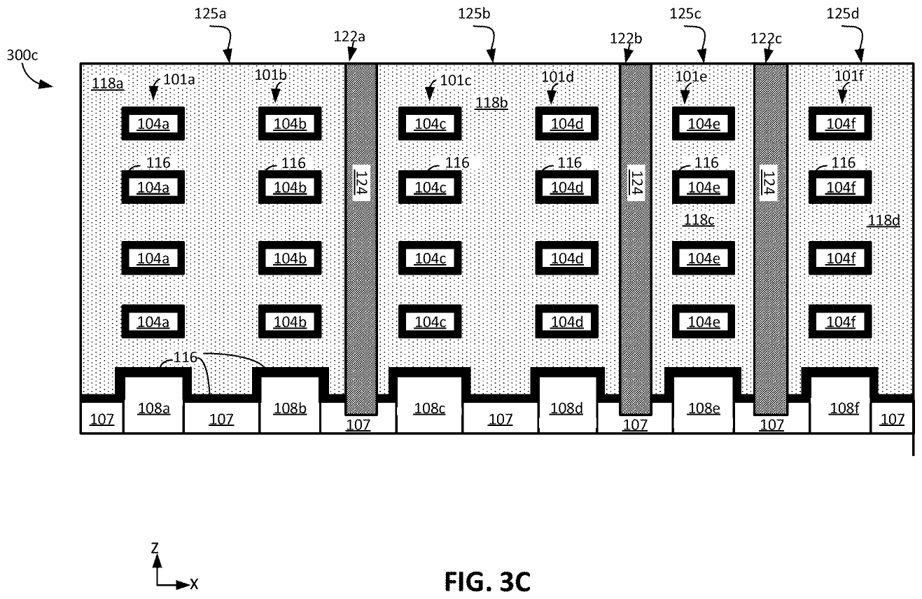

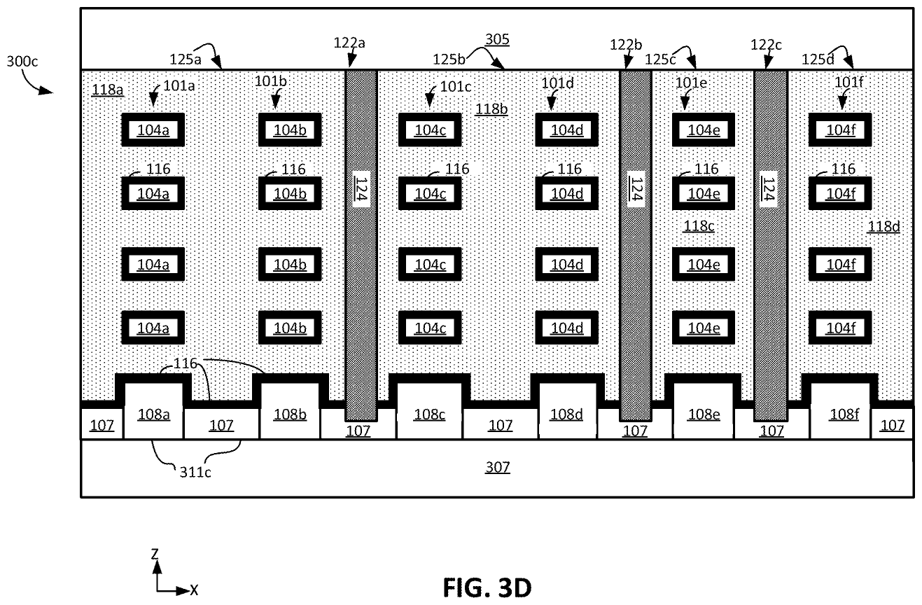

As can be seen, in the example of FIG. 1A, devices 101 are formed on a substrate 102 (although a part of or the entirety of the substrate 102 may be polished off from the backside in another example, see FIGS. 3A-3D). Any number of semiconductor devices 101 can be formed on substrate 102, but six are illustrated here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used. In some embodiments, a lower portion of (or all of) substrate 102 is removed and replaced with one or more backside interconnect layers to form backside signal and power routing, during a backside process.

The structure 100 comprises sub-fin regions 108a, . . . , 108f, such that the devices 104a, . . . , 104f each include a corresponding sub-fin region 108. According to some embodiments, sub-fin regions 108 comprise the same semiconductor material as substrate 102 and is adjacent to dielectric materials 106, 107.

According to some embodiments, nanoribbons 104 (or other semiconductor bodies, such as nanowires, nanosheets, or fin-based structures) of a device 101 is above a corresponding sub-fin 108. For example, the nanoribbons 104a of the device 101a is above the corresponding sub-fin 108a, the nanoribbons 104b of the device 101b is above the corresponding sub-fin 108b, and so on.

The nanoribbons 104 of a device extend between corresponding source and drain regions 110 (where source and drain regions of device 101c are illustrated in FIG. 1B) in the first direction (e.g., along the Y-axis of FIG. 1B). For example, nanoribbons 104a provide an active channel region for a corresponding transistor device 101a, nanoribbons 104b provide an active channel region for a corresponding transistor device 101b, nanoribbons 104f provide an active channel region for a corresponding transistor device 101f, and so on.

As illustrated in the cross-sectional view of device 101c of FIG. 1B, a source region 110c1 is on a first side of corresponding nanoribbons 104c, and a drain region 110c2 is on a second side of corresponding nanoribbons 104c, such that the nanoribbons 104c extend laterally from the source region 110c1 to the drain region 110c2. Similarly, nanoribbons 104a extend laterally from a corresponding source region 110a1 to a corresponding drain region 110a2, nanoribbons 104b extend laterally from a corresponding source region 110b1 to a corresponding drain region 110b2, and so on, although only the source and drain regions 110c1, 110c2 of the device 101c are illustrated in the cross-sectional view of FIG. 1B. Note that the source and drain regions are not illustrated in the cross-sectional view of FIG. 1A, as the various source or drain regions of the devices 101 would be in front or back of the plane of the paper in which the cross-sectional view of FIG. 1A is illustrated.

According to some embodiments, source and drain regions 110 are epitaxial regions that are provided using an etch-and-replace process. In other embodiments source or drain regions 110 could be, for example, implantation-doped native portions of the semiconductor fins or substrate. Any semiconductor materials suitable for source and drain regions can be used (e.g., group IV and group III-V semiconductor materials). Source or drain regions 110 may include multiple layers such as liners and capping layers to improve contact resistance. In any such cases, the composition and doping of source or drain regions 110 may be the same or different, depending on the polarity of the transistors. In an example, for instance, one of the devices 101a, . . . , 101f is a p-type MOS (PMOS) transistor, an adjacent one of the devices is an n-type MOS (NMOS) transistor, and so on. Any number of source and drain configurations and materials can be used.

In an example, in the device 101c of FIG. 1B, conductive contacts 147c1 and 147c2 are respectively above the source region 110c1 and the drain region 110c2. One or more other source and/or drain regions of the other devices may also have corresponding contacts. The conductive source and drain contacts may be any suitably conductive material, such as one or more metals and/or alloys thereof. In some embodiments, conductive contacts include one or more of the same metal materials as gate electrode, or a different conductive material. Conductive contacts 147 may be any suitably conductive material such as tungsten (W), copper (Cu), ruthenium (Ru), cobalt (Co), titanium (Ti), molybdenum (Mo), or any alloys thereof. Contacts 147 may include multiple layers, such as a silicide (e.g., tungsten silicide) or a germanide, and a fill metal (e.g., tungsten).

According to some embodiments, a lower dielectric layer 112 exists beneath source and drain regions 110. Lower dielectric layer 112 can include any suitable dielectric material, such as silicon oxide or silicon nitride, and may be provided to isolate source and drain regions 110 from sub-fin regions 108.

According to some embodiments, individual gate structures 125a, 125b, 125c, 125d extend over corresponding nanoribbons 104 along a second direction (e.g., in the direction of the X-axis of FIG. 1A and across the page of FIG. 1A). For example, as illustrated in FIG. 1A, gate structure 125a extends over and is on the nanoribbons 104a, 104b of the devices 101a, 101b, respectively; gate structure 125b extends over and is on the nanoribbons 104c, 104d of the devices 101c, 101d, respectively; gate structure 125c extends over and is on the nanoribbons 104e of the device 101e; and gate structure 125d extends over and is on the nanoribbons 104f of the device 101f.

In one embodiment, each gate structure 125 includes a gate dielectric 116 that wraps around middle portions of each corresponding nanoribbon 104, and a gate electrode 118 that wraps around the gate dielectric 116. For example, gate structure 125a includes gate dielectric 116 wrapping around nanoribbons 104a and 104b, and gate electrode 118a. Similarly, gate structure 125b includes gate dielectric 116 wrapping around nanoribbons 104c and 104d, and gate electrode 118b, and so on.

In an example, the gate dielectric 116 is present around middle portions of each nanoribbon 104, and may also be present over sub-fin 108 and dielectric material 107 (discussed herein later, see FIG. 1A), and/or on inner sidewalls of the inner gate spacers 145 (see FIG. 1B).

In some embodiments, the gate dielectric 116 may include a single material layer or multiple stacked material layers. The gate dielectric 116 may include, for example, any suitable oxide (such as silicon dioxide), high-k dielectric material, and/or any other suitable material as will be apparent in light of this disclosure. Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. The high-k dielectric material (e.g., hafnium oxide) may be doped with an element to affect the threshold voltage of the given semiconductor device. According to some embodiments, the doping element used in gate dielectric 116 is lanthanum. In some embodiments, the gate dielectric can be annealed to improve its quality when high-k dielectric material is used. In some embodiments, the gate dielectric 116 includes a first layer (e.g., native oxide of nanoribbons, such as silicon dioxide or germanium oxide or SiGe-oxide) on the nanoribbons, and a second layer of high-k dielectric (e.g., hafnium oxide) on the first layer.

The gate electrode 118a of the gate structure 125a wraps around middle portions of individual nanoribbons 104a and 104b; the gate electrode 118b of the gate structure 125b wraps around middle portions of individual nanoribbons 104c and 104d; the gate electrode 118c of the gate structure 125c wraps around middle portions of individual nanoribbons 104e; and the gate electrode 118d of the gate structure 125d wraps around middle portions of individual nanoribbons 104f. Note that the middle portion of each nanoribbon 104 is between a corresponding first end portion and a second end portion, where the first end portions of the nanoribbons of a stack is wrapped around by corresponding first inner gate spacer 145, and where the second end portions of the nanoribbons of the stack is wrapped around by corresponding second inner gate spacer 145, where the inner gate spacers 145 for the device 101c are illustrated in FIG. 1B. Other devices have similar inner gate spacers. Also illustrated in FIG. 1B for the device 101c are gate spacers 149 that separate upper portions of the gate electrode 118c (or a gate contact above the gate electrode 118c) from the conductive source and drain contacts 147c1, 147c2. Gate spacers 149 can include any suitable dielectric material, such as silicon oxide or silicon nitride

In one embodiment, one or more work function materials (not illustrated in FIGS. 1A and 1B) may be included around the nanoribbons 104. Note that work function materials are called out separately, but may be considered to be part of the gate electrodes. In this manner, a gate electrode 118 may include multiple layers or components, including one or more work function materials, gate fill material, capping or resistance-reducing material, to name a few examples. In some embodiments, a p-channel device may include a work function metal having titanium, and an n-channel device may include a work function metal having tungsten or aluminum, although other material and combination may also be possible. In some other embodiments, the work function metal may be absent around one or more nanoribbons. In still other embodiments, there may be insufficient room for any gate fill material, after deposition of work function material (i.e., a given gate electrode may be all work function material and no fill material). In an example, the gate electrodes 118 may include any sufficiently conductive material, such as a metal, metal alloy, or doped polysilicon. The gate electrodes may include a wide range of materials, such as polysilicon or various suitable metals or metal alloys, such as aluminum, tungsten, titanium, tantalum, copper, cobalt, molybdenum, titanium nitride, or tantalum nitride, for example. Numerous gate structure configurations can be used along with the techniques provided herein, and the present disclosure is not intended to be limited to any particular such configurations.

As discussed herein above, each gate structure 125 also includes two corresponding inner gate spacers 145 that extend along the sides of the gate electrode 118, to isolate the gate electrode 118 from an adjacent source or drain region. The inner gate spacers 145 at least partially surround the end portions of individual nanoribbons. In one embodiment, gate spacers 145 may include a dielectric material, such as silicon nitride, for example.

In one embodiment, adjacent gate structures are separated along the second direction (e.g., in the X-axis direction of FIG. 1A) by a corresponding gate cut 122, which acts like a dielectric barrier between gate structures. For example, a gate cut 122a laterally separates the gate structures 125a and 125b, a gate cut 122b laterally separates the gate structures 125b and 125c, and a gate cut 122c laterally separates the gate structures 125c and 125d. Individual gate cuts 122 comprise a corresponding structure of sufficiently insulating material, such as a structure of dielectric material 124. Example dielectric materials 124 for gate cut 122 include silicon nitride (SiN), silicon oxide (SiO), silicon carbide (SiC), silicon oxycarbide (SiOC), silicon oxycarbonitride (SiOCN), or silicon oxynitride (SiON), e.g., include silicon and one or more of oxygen, carbon, or nitrogen. In some cases, gate cuts 122 may include multiple layers of dielectric material, such as a first layer of high-k dielectric material along the outer sidewalls of the gate cut structure, and a second layer or body of low-k dielectric material that fills in the remaining portion of the given gate cut 122. In some examples, gate cuts 122 may include one or more airgaps or voids (e.g., filled with gas such as oxygen and/or nitrogen, or devoid of gas). More generally, a given gate cut 122 may include any number of dielectric layers or bodies, and the overall gate cut structure can vary from one embodiment to the next. In an example, since a gate cut 122 is formed after the formation of the gate structures, gate dielectric 116 are not present along the sidewalls of gate cut 122 within the gate trench. According to some embodiments, gate cut 122 also extends in the first direction (into and out of the page of FIG. 1A, e.g., in the Y-axis direction) such that it may cut across a portion of source or drain regions 110.

Note that each of the gate structures 125a, 125b are on two corresponding devices, while each of the gate structures 125c, 125d are on one corresponding device. A number of devices (e.g., one, two, three, or higher) on which a continuous gate structure is may depend on a design or architecture of a circuit implemented by the devices 101, and is implementation specific. In an example, locations and/or a number of gate cuts are implementation specific, and are based on a circuit implemented by the structure 100.

As can further be seen in FIG. 1A, adjacent semiconductor devices are separated by dielectric materials 106 and 107. For example, the dielectric material 106 is between sub-fins of two adjacent devices, such as between sub-fins 108a and 108b of the devices 101a and 101b, between sub-fins 108b and 108c of the devices 101b and 101c, and so on. Dielectric material 106 provides shallow trench isolation (STI) between any adjacent semiconductor devices. Dielectric material 106 can be any suitable dielectric material, such as silicon oxide (SiO), silicon nitride (SiN), silicon carbide (SiC), silicon oxycarbide (SiOC), silicon oxycarbonitride (SiOCN), or silicon oxynitride (SiON), for example.

The dielectric material 107 is also between adjacent sub-fins, and above the dielectric material 106. For example, the dielectric material 107 is between sub-fins 108a and 108b of the devices 101a and 101b and above the dielectric material 106, between sub-fins 108b and 108c of the devices 101b and 101c and above the dielectric material 106, and so on.

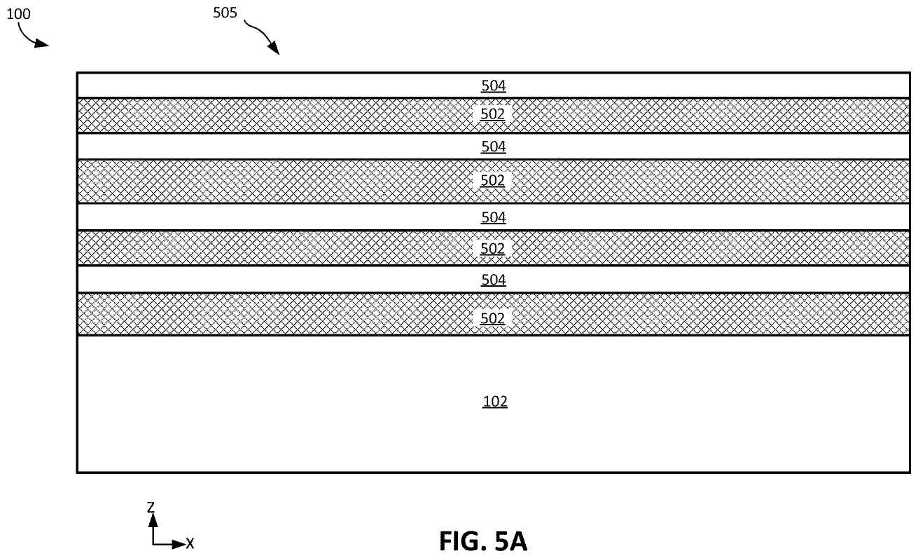

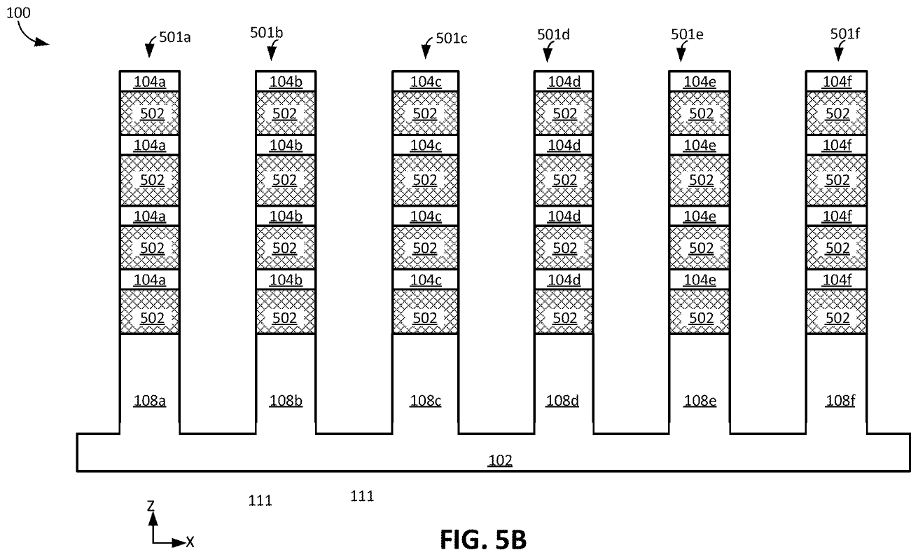

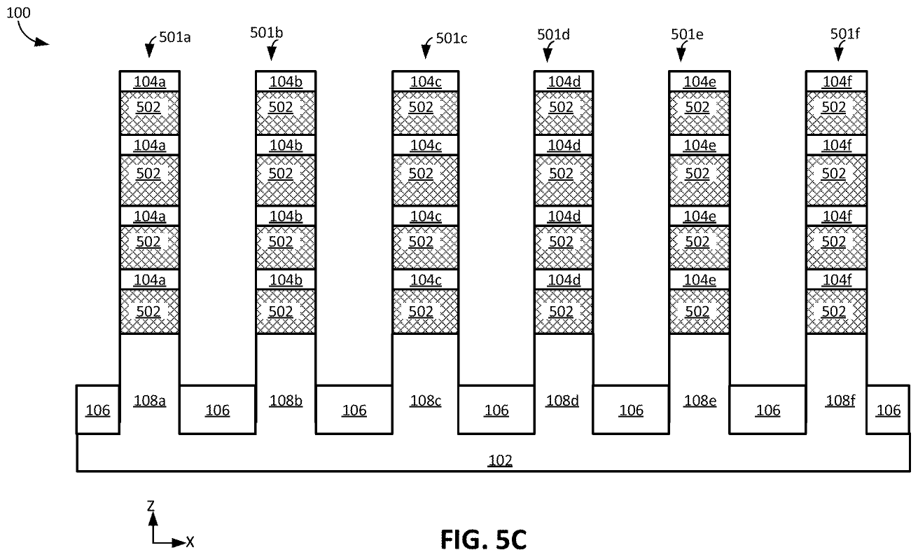

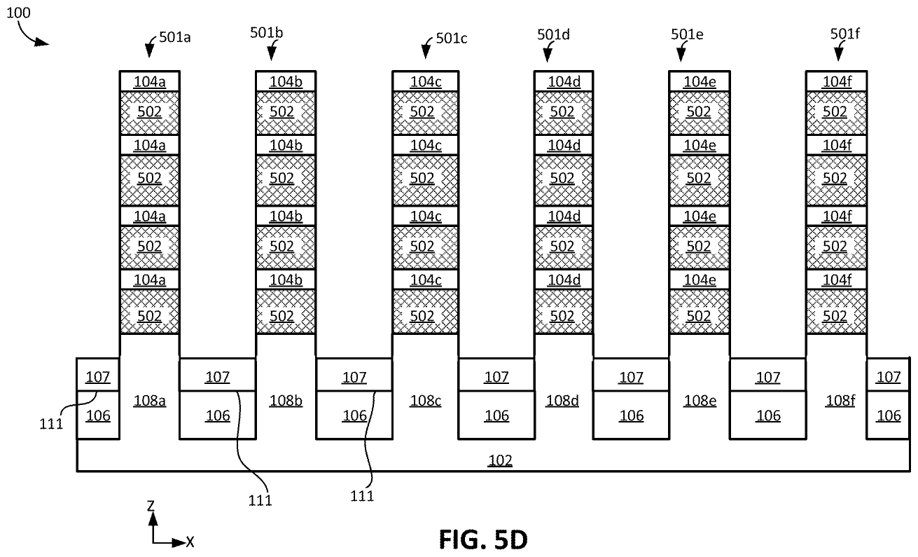

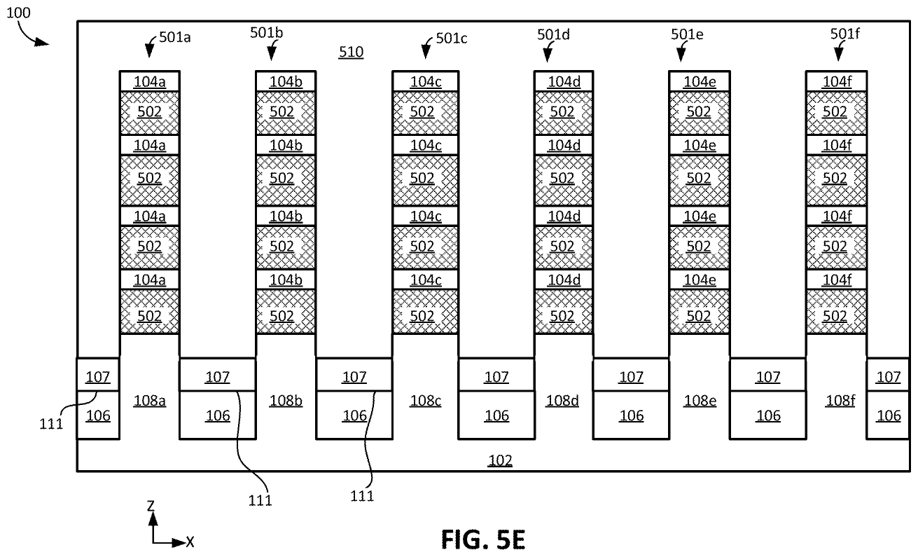

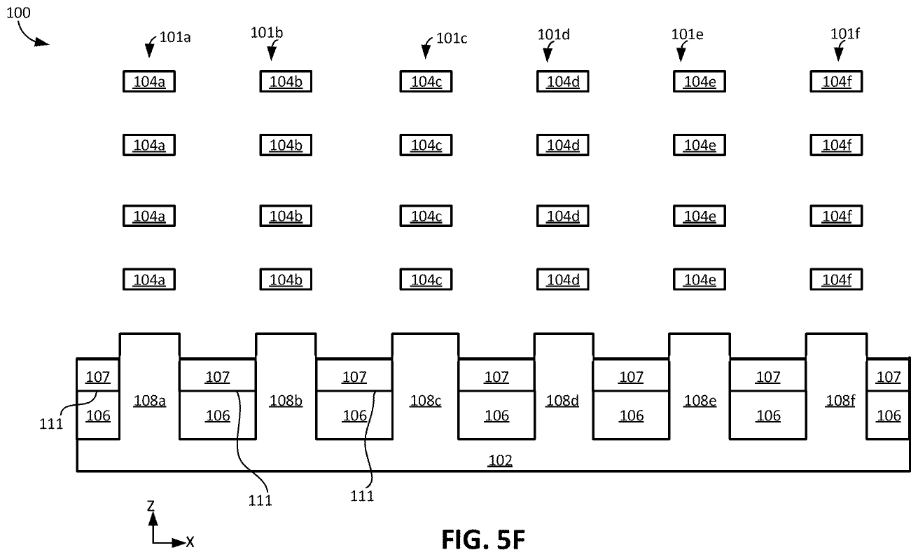

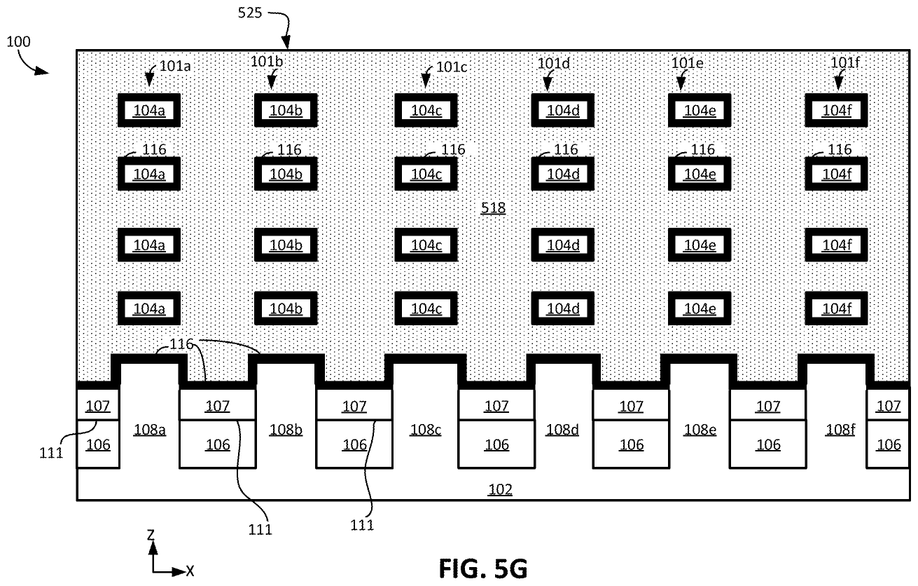

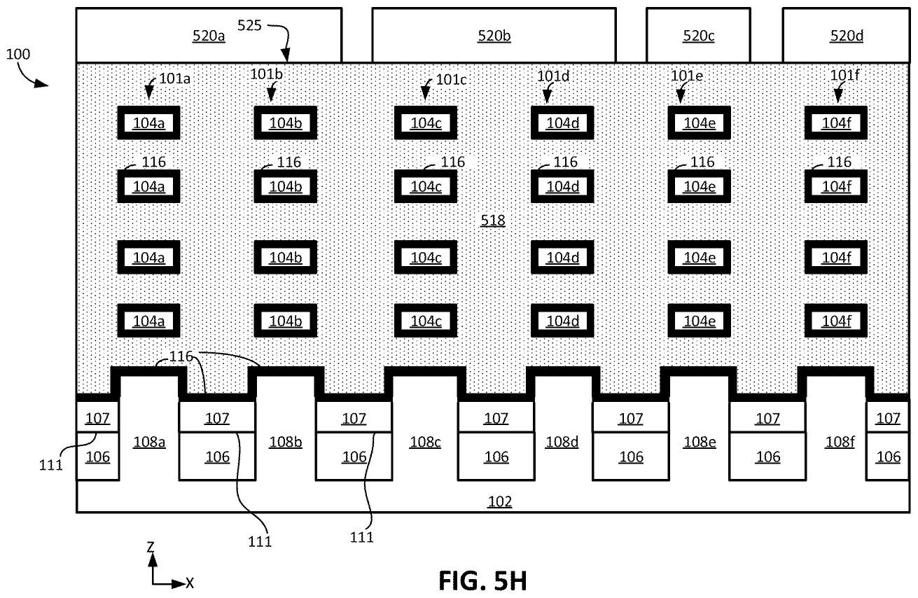

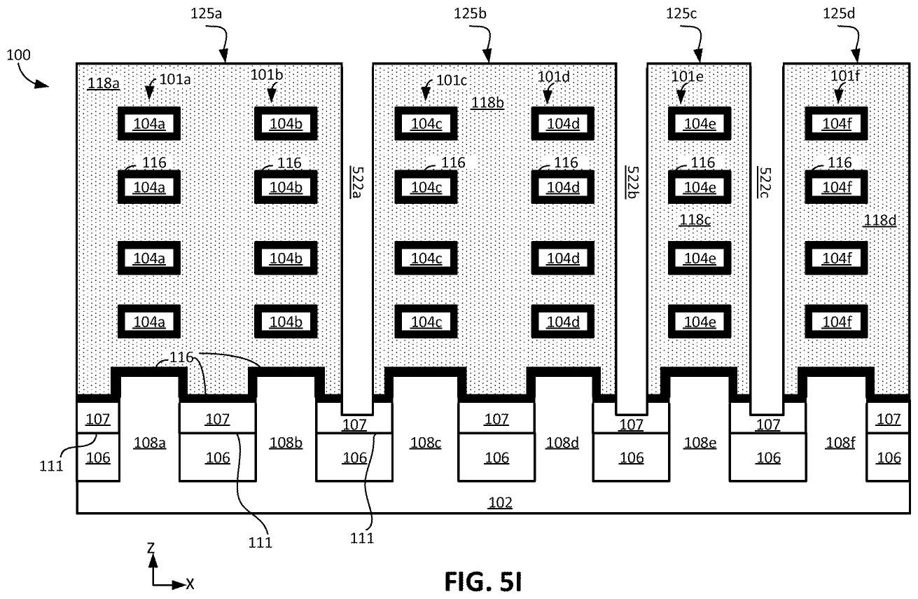

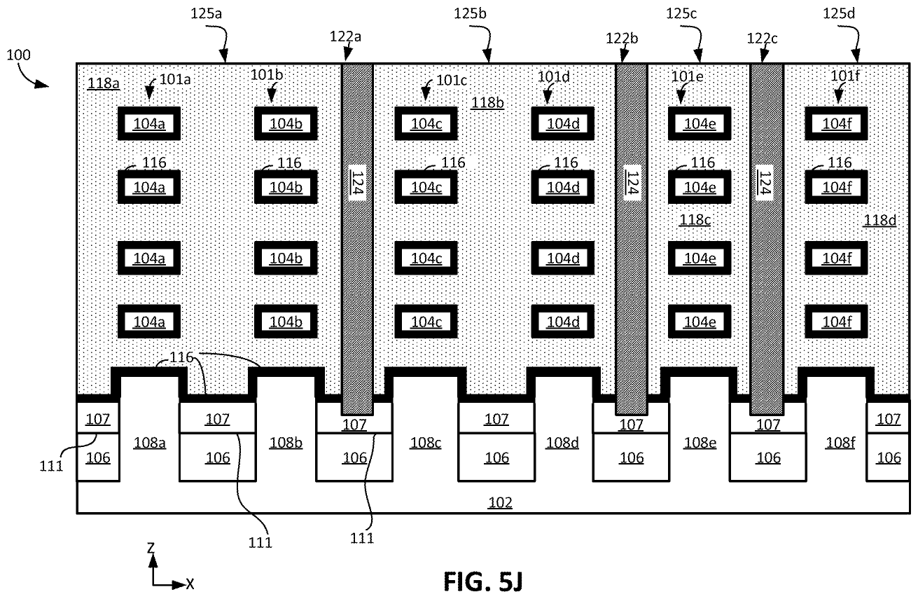

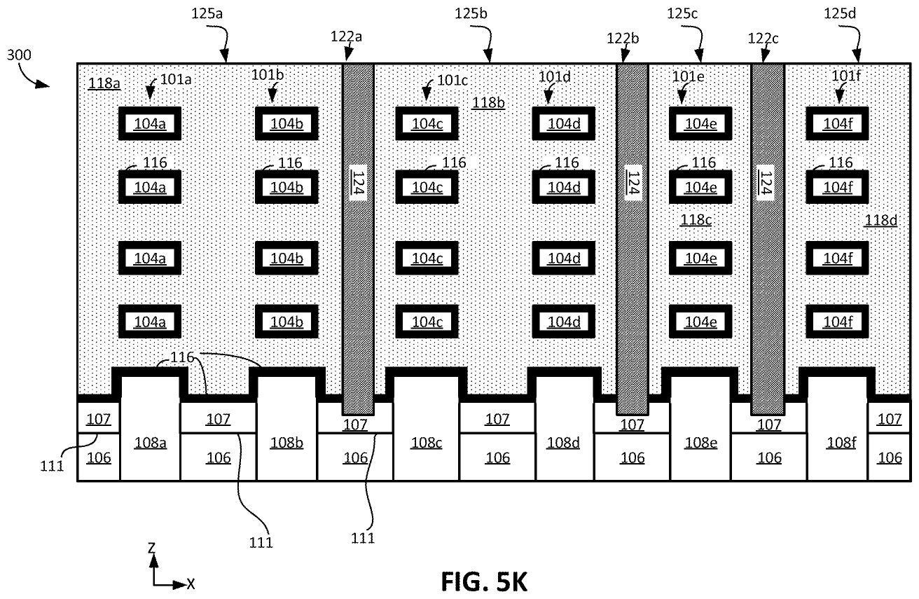

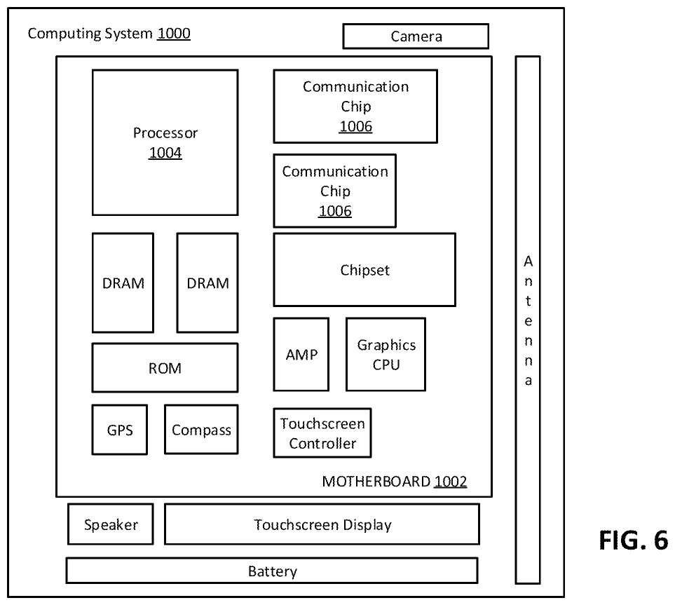

In an example, the dielectric material 107 acts as an etch stop layer, e.g., when the recess for the gate cut 122 is formed through the metal gate electrode. Thus, the dielectric material 107 can be any suitable dielectric material that can also act as an etch stop layer during the metal gate etch process, as discussed with respect to FIG. 5F. Examples of the dielectric material 107 include silicon nitride (SiN), silicon oxynitride (SiON), silicon carbide (SiC), silicon oxycarbide (SiOC), silicon oxycarbonitride (SiOCN), or silicon oxide (SiO), for example.

For example, the metal gate etch process that etches through the metal gate electrode may not substantially etch, or etch at a lower rate, the dielectric material 107. Accordingly, each of the gate cuts 122 extend partially through the dielectric material 107, but doesn't punches through (e.g., extend fully through) the dielectric material 107.

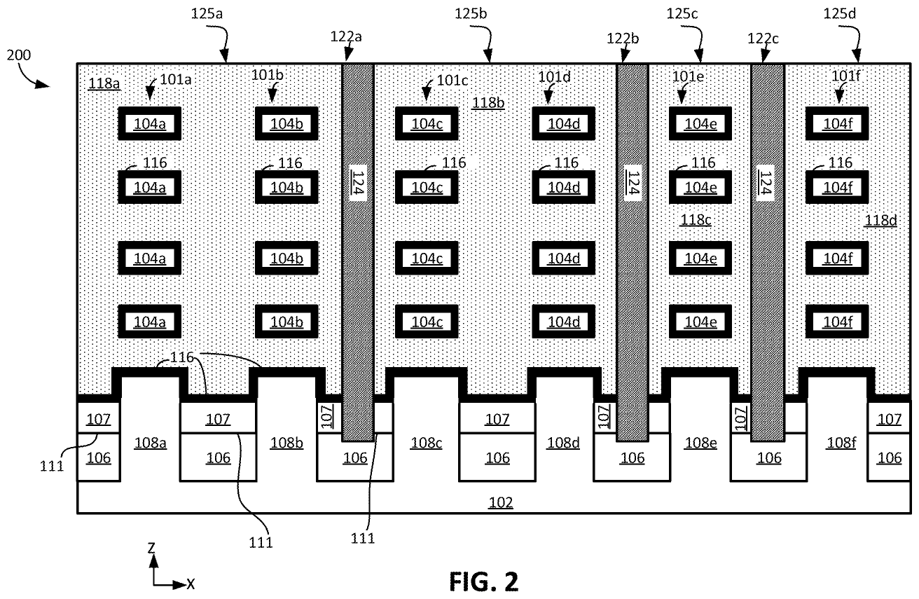

In an example, the dielectric material 107, e.g., the etch stop layer, allows for the gate cuts to have a relatively uniform height (e.g., within 10 nm of one another, or within 5 nm of each other), relative to a configuration where there is no underlying etch stop and the gate cut heights can vary greatly (e.g., gate cut height variance of over 20 nm). More generally, the etch stop dielectric material 107 operates to stop, or to otherwise slow down the gate cut trench etch (discussed herein later with respect to FIG. 5I) so as to effectively dampen the variation in any punch-through etch (see FIG. 2, where the gate cut trench may punch through the dielectric material 107). Accordingly, the gate cut trenches may not reach or extend past the sub-fin bottoms and into the substrate 102, as the gate cut trenches may be stopped by the etch stop dielectric material 107, or otherwise more uniformly pass there-trough and stop at the dielectric material 106 (see FIG. 2). For instance, in some such example cases, the trenches land on the etch stop dielectric material 107 or within the etch stop dielectric material 107. In other such example cases, the trenches pass-through the etch stop dielectric material 107 (see FIG. 2) but only extend into the underlying dielectric material 106 by no more than a threshold distance of 10 nm or 20 nm and in a relatively uniform fashion, or otherwise do not extend past the sub-fin bottoms and into the underlying substrate 102.

In an example, the substrate 102 (or at least a part thereof) may be polished and removed from the backside (see FIGS. 3A-3D), such as the example case where the backside polish generally stops at the bottom surface of the trough between fins so as to define the sub-fin bottom surfaces. In a standard process, any gate cut trenches extending into the substrate can make the backside polishing process of the substrate difficult. However, the etch stop dielectric material 107 described herein stops the gate cut trenches from reaching the backside portion of the substrate to be removed, thereby avoiding any such difficulty in the backside polishing process.

In an example, the dielectric material 106 is elementally and/or compositionally different from the dielectric material 107, although in another example the dielectric materials 106 and 107 may be elementally (and possibly compositionally) same. Examples of the dielectric materials 106, 107 have been discussed herein above, and in one example, the dielectric material 106 comprise an oxide, such as silicon oxide, and the dielectric material 107 comprise a nitride, such as silicon nitride. In an example (and as also discussed with respect to FIGS. 5C and 5D), the dielectric materials 106 and 107 are deposited using different deposition processes. Accordingly, an interface 111, such as a seam or a grain boundary, is formed between a stack of the dielectric materials 106 and 107, as illustrated in FIG. 1A.

In an example, the dielectric material 107 has a vertical height h1 and the dielectric material 106 has a vertical height h2 (see FIG. 1A), where the heights h1 and h2 are measured in a direction (e.g., Z-axis direction) that is perpendicular to a length of the nanoribbons 104 (e.g., Y-axis direction) and perpendicular to a length of the gate electrodes 118 (e.g., X-axis direction). In an example, the dielectric material 107 is deposited conformally as a relatively thin layer, e.g., compared to a height of the dielectric material 106. Accordingly, in an example, the height h2 is greater than h1 by at least 10%, or at least 20%, or at least 30%, or at least 40%, or at least 50%, or at least 75%, or at least 100%, or at least 200%, or at least 250%, for example.

FIG. 2 illustrates a cross-sectional view of another integrated circuit structure 200 that is at least in part similar to the integrated circuit structure 100 of FIGS. 1A-1B, wherein the gate cut 122a between devices 101b and 101c in the structure 200 of FIG. 2 extends fully within and through the second dielectric material 107, and is in contact with the first dielectric material 106, according to an embodiment of the present disclosure.

The integrated circuit structures 100 and 200 are at least in part similar, and similar components are illustrated using similar labels. For example, similar to the structure 100, the structure 200 comprises devices 101a, . . . , 101f, each device 101 comprising corresponding nanoribbons 104 and corresponding source and drain regions (although the source or drain regions are not visible in the view of FIG. 2), gate cuts 122a, 122b, 122c, and stacks of dielectric materials 106, 107.

However, in FIG. 1A, the gate cuts 122 extend partially within the dielectric material 107. In contrast, in the example of FIG. 2, the gate cut extends fully through (e.g., punches through) the dielectric material 107, and extends within the dielectric material 106.

FIG. 3A illustrates a cross-sectional view of another integrated circuit structure 300 that is at least in part similar to the integrated circuit structure 100 of FIGS. 1A-1B, wherein a substrate 102 has been planarized and polished off at least in part (or fully) from the backside of the structure 300 of FIG. 3A, according to an embodiment of the present disclosure. Although FIG. 3A illustrates an example in which the substrate 102 of FIG. 1A has been fully removed, in another example, the substrate 102 can be at least partially removed. In an example, removal of the substrate 102 facilitates in forming backside contacts for the source, drain, and/or gate structures, and/or facilitates in forming backside interconnect features for backside signal and/or power routing.

FIG. 3B illustrates the integrated circuit structure 300 of FIG. 3A, with a frontside interconnect structure 305 above and a backside interconnect structure 307 below the integrated circuit structure 300 of FIG. 3B, according to an embodiment of the present disclosure. In an example, each of the interconnect structures 305, 307 comprise one or more interconnect layers. Each interconnect layer comprises corresponding dielectric material (e.g., which may be compositionally different from the dielectric material 107), and one or more conductive interconnect features extending within the dielectric material, where the conductive interconnect features are conductive vias and/or lines used for routing power and signals within the integrated circuit. In an example, instead of both the frontside interconnect structure 305 and the backside interconnect structure 307, only one (e.g., the backside interconnect structure 307) may be present within the structure 300. In an example, the backside interconnect structure 307 facilitates routing of source, drain, and/or gate signals, and/or for backside signal and/or power routing. In an example, an interface 311 (such as a seam or a grain boundary) is between (i) bottom surfaces of the dielectric material 106 and the sub-fins 108, and (ii) top surface of the dielectric material of the backside interconnect structure 307.

FIG. 3C illustrates a cross-sectional view of another integrated circuit structure 300c that is at least in part similar to the integrated circuit structure 100 of FIGS. 1A-1B, wherein the substrate 102 and the first dielectric material 106 has been polished off at least in part (or fully) from the backside of the structure 300c of FIG. 3C, according to an embodiment of the present disclosure. Thus, the dielectric material 107 are exposed through the backside of the structure 300.

Note that in an example, the dielectric material 107 may also be at least in part polished and removed from the backside, along with bottom portions of the sub-fins. In some such examples, at least some remnants of the dielectric material 107 may still be present laterally between remnants of the sub-fins, and between the gate structures and a backside interconnect structure 307 (see FIG. 3D). In one example, remnants of the dielectric material 107 may be found underneath the sub-fins 108 as well, where trace remnants of the dielectric material 107 may move under the sub-fins 108 during the polishing process.

FIG. 3D illustrates the integrated circuit structure 300c of FIG. 3C, with a frontside interconnect structure 305 above and a backside interconnect structure 307 below the integrated circuit structure 300c of FIG. 3C, according to an embodiment of the present disclosure. In an example, each of the interconnect structures 305, 307 comprise one or more interconnect layers. Each interconnect layer comprises corresponding dielectric material (e.g., which may be compositionally different from the dielectric material 107), and one or more conductive interconnect features extending within the dielectric material, where the conductive interconnect features are conductive vias and/or lines used for routing power and signals within the integrated circuit. In an example, instead of both the frontside interconnect structure 305 and the backside interconnect structure 307, only one (e.g., the backside interconnect structure 307) may be present within the structure 300. In an example, the backside interconnect structure 307 facilitates routing of source, drain, and/or gate signals, and/or for backside signal and/or power routing. In an example, an interface 311c (such as a seam or a grain boundary) is between (i) bottom surfaces of the dielectric material 107 and the sub-fins 108, and (ii) top surface of the dielectric material of the backside interconnect structure 307.

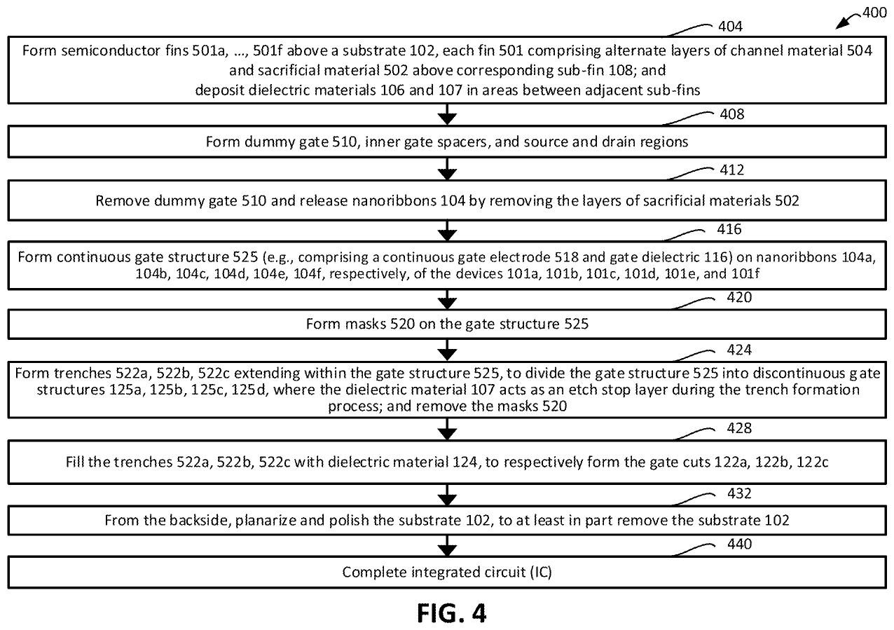

FIG. 4 illustrates a flowchart depicting a method 400 of forming the integrated circuit structures of FIGS. 1A, 1B, 2, and 3A-3D, in accordance with an embodiment of the present disclosure. FIGS. 5A, 5B, 5C, 5D, 5E, 5F, 5G, 5H, 5I, 5J, and 5K collectively illustrate cross-sectional views of an integrated circuit structure in various stages of processing in accordance with the methodology 400 of FIG. 4, in accordance with an embodiment of the present disclosure. FIGS. 4 and 5A-5I will be discussed in unison.

Each of FIGS. 5A-5K illustrate cross-sectional views taken across a gate structure portion of the integrated circuit, similar to the view of FIG. 1A. Accordingly, formation of the source or drain regions 110 and inner gate spacers 116 (see FIG. 1B) are not illustrated in the cross-sectional views of FIGS. 5A-5K.

Referring to FIG. 4, the method 400 includes, at 404, forming semiconductor fins 501a, . . . , 501f, each fin 501 comprising alternate layers of channel material 504 and sacrificial material 502 above corresponding sub-fin 108, as illustrated in FIGS. 5A-5B. For example, to form the fins 501, a stack 505 of alternating layers of channel material 504 and sacrificial material 502 are deposited above the substrate 102, as illustrated in FIG. 5A. Any number of alternating layers of channel material 504 and sacrificial material 502 may be deposited, e.g., depending on a target number of nanoribbons per device.

According to some embodiments, the sacrificial material 502 have a different material composition than the channel material 504. In some embodiments, the sacrificial material 502 comprises silicon germanium (SiGe), while the channel material 504 includes a semiconductor material suitable for use as a nanoribbon such as silicon (Si), SiGe, germanium, or III-V materials like indium phosphide (InP) or gallium arsenide (GaAs). In examples where SiGe is used in the sacrificial material 502 and in semiconductor layers 204, the germanium concentration is different between the sacrificial material 502 and the channel material 502. For example, the sacrificial material 502 may include a higher germanium content compared to the channel material 504. In some examples, the channel material 504 may be doped with either n-type dopants (to produce a p-channel transistor) or p-type dopants (to produce an n-channel transistor). While dimensions can vary from one example embodiment to the next, the thickness of each layer of sacrificial material 502 may be between about 5 nm and about 20 nm. In some embodiments, the thickness of each layer of sacrificial material 502 may substantially be the same (e.g., within 1-2 nm). The thickness of each of layer of channel material 504 may be about the same as the thickness of each layer of sacrificial material 502 (e.g., about 5-20 nm), although it may be different in another example. Each of the layers of sacrificial material 502 and channel material 504 may be deposited using any known or proprietary material deposition technique, such as chemical vapor deposition (CVD), plasma-enhanced chemical vapor deposition (PECVD), physical vapor deposition (PVD), or atomic layer deposition (ALD), for example.

In an example, the fins 501 of FIG. 5B may be formed from the stack 505 of FIG. 5A by appropriately patterning the stack 505. For example, suitable masks (such as carbon hard mask or CHM) may be used to pattern the stack 505, to form the rows of fins 501a, . . . , 501f, e.g., using appropriate techniques to form fins in GAA transistors. Note that during the etch process for formation of the fins 501, portions of the substrate 102 may also be etched, as illustrated in FIG. 5B.

Also at 404 of method 400, dielectric materials 106 and 107 are deposited in areas between adjacent sub-fins, as illustrated in FIGS. 5C and 5D. For example, the dielectric materials 106 and 107 are deposited at least in part in the etched portions of the substrate 102.

In an example, the dielectric materials 106 and 107 are elementally and/or compositionally different, and may be deposited using different deposition processes, see FIGS. 5C and 5D. Accordingly, an interface 111 may be formed between vertically stacked dielectric materials 106, 107. Each of the layers of dielectric materials 106, 107 may be deposited using any known or proprietary material deposition technique, such as CVD, PECVD, PVD, or ALD, for example. Examples of the dielectric materials 106, 107 have been described above.

Note that in an example, to form the dielectric material 106 between the adjacent sub-fins, the dielectric material 106 may be blanket deposited on an entire portion of at least a section of the wafer, such as between adjacent sub-fins, as well as above the fins 501. Subsequently, portions of the dielectric material 106 above the fins 501 may be etched, e.g., while other portions of the dielectric material 106 between adjacent sub-fins are protected using a mask (such as CHM). In another example, the dielectric material 106 is deposited to fill the entire trench between adjacent fins, and then the deposited dielectric material 106 is recessed from top, such that dielectric material 106 between adjacent sub-fins remain. The dielectric material 107 may also be similarly formed between adjacent sub-fins and above the dielectric material 106. In an example and as discussed with respect to FIG. 1A, a height of the dielectric material 107 may be less than a height h2 of the dielectric material 106.

Referring again to FIG. 4, the method 400 then proceeds from 404 to 408, where dummy gate 510, inner gate spacers 116, and source and drain regions 110 are formed. FIG. 5D illustrates the dummy gate 510. The inner gate spacers 116 and the source and drain regions 110 are not visible in the cross-section views of FIG. 5D, and hence, formation of these components is not separately illustrated. The dummy gate 510 extending across the fins 501 in a direction of X-axis, as illustrated. Dummy gate 510 may be any suitable material that can be selectively removed without damaging the semiconductor material of the fins. In some examples, dummy gate 510 includes polysilicon. The dummy gate 510 is on the fins 501, and not on sections in which the source or drain regions are to be formed. Although not illustrated, to form the source or drain regions, source and drain trenches are formed within the fins (e.g., in sections of each fin that are in front of and on back of the plane of the paper), and end sections of the sacrificial materials 502 (e.g., in front of and on back of the plane of the paper) of the fins are recessed and inner gate spacers 116 (see FIG. 1B) are formed within such recesses. The end sections of the channel materials 504 are exposed through the inner gate spacers. Subsequently, the source or drain regions are epitaxially grown, to be in contact with the corresponding end sections of the channel materials 504, e.g., in front of and back of the plane of the paper of FIG. 5E. The dummy gate 510, the inner spacers 116, and the source or drain regions 110 are formed using appropriate techniques for forming these components in GAA transistors.

Referring again to FIG. 4, the method 400 then proceeds from 408 to 412, where the dummy gate 510 is removed, and the nanoribbons 104 are released by removing the layers of sacrificial materials 502, as illustrated in FIG. 5F. Note that in FIG. 5F, the end sections of each nanoribbon 104 are supported by corresponding source and regions, which are in front and back of the paper.

In an example, the dummy gate 510 is removed via an etch process that is selective to the inner gate spacers and other non-gate materials exposed during channel and gate processing. Removing the dummy gate electrode between the inner gate spacers exposes the channel region of the fins. For example, a polycrystalline silicon dummy gate electrode can be removed using a wet etch process (e.g., nitric acid/hydrofluoric acid), an anisotropic dry etch, or other suitable etch process, as will be appreciated. At this stage of processing, the alternating layers of channel material and sacrificial material of each fin are exposed in the channel region.

The layers of sacrificial material 502 in each fin can then be removed by etch processing, to release the nanoribbons 104, in accordance with some embodiments. Etching the sacrificial material 502 may be performed using any suitable wet or dry etching process such that the etch process selectively removes the sacrificial material and leaves intact the channel material. In one embodiment, the sacrificial material is silicon germanium (SiGe) and the channel material is electronic grade silicon (Si). For example, a gas-phase etch using an oxidizer and hydrofluoric acid (HF) has shown to selectively etch SiGe in SiGe/Si layer stacks. In another embodiment, a gas-phase chlorine trifluoride (ClF3) etch is used to remove the sacrificial SiGe material. The etch chemistry can be selected based on the germanium concentration, nanoribbon dimensions, and other factors, as will be appreciated. After removing the SiGe sacrificial material, the resulting channel region includes silicon nanoribbons 104 extending between corresponding source and drain regions.

Referring again to FIG. 4, the method 400 then proceeds from 412 to 416, where a continuous gate structure 525 (e.g., comprising a continuous gate electrode 518 and gate dielectric 116) is formed on nanoribbons 104a, 104b, 104c, 104d, 104e, 104f, respectively, of the devices 101a, 101b, 101c, 101d, 101e, and 101f, as illustrated in FIG. 5G. Gate dielectric 116 may be conformally deposited around the nanoribbons 104, as well as on inner walls of inner gate spacers and above the sub-fins 108 and dielectric material 107, using any suitable deposition process, such as ALD. Gate electrode 518 may be deposited over gate dielectric 116, which can be any standard or proprietary conductive structure. As described above, gate electrode 518 may include, for instance, one or more workfunction layers, resistance-reducing layers, and/or barrier layers. Example materials of various components of the gate structure 525 have been described herein above.

Referring again to FIG. 4, the method 400 then proceeds from 416 to 420, where masks 520 are formed on the gate structure 525, as illustrated in FIG. 5H. For example, the masks 520 are formed on areas of the gate structure 525 that are not to be removed during formation of the gate cuts 122.

In an example, the masks 520 may comprise an appropriate material that is etch selective to the material of the gate electrode 518 (e.g., an etch process to etch the gate electrode 518 may not substantially etch the masks 520, and an etch process to etch the masks 520 may not substantially etch the gate electrode 518). The masks 520 comprise CHM or silicon nitride, for example.

Referring again to FIG. 4, the method 400 then proceeds from 420 to 424, where trenches 522a, 522b, 522c are formed to extend within the gate structure 525, to divide the gate structure 525 into discontinuous gate structures 125a, 125b, 125c, 125d, as illustrated in FIG. 5I As described herein above, the dielectric material 107 acts as an etch stop layer during the trench formation process. For example, an appropriate metal etch process may be employed to form the trenches. The metal gate etch process iteratively etches through portions of gate electrode 525 not covered by the masks 520. The masks 520 protects the gate structures 125a, 125b, 125c, 125d from being etched, while the trenches 522a, 522b, 522c are being formed through uncovered sections of the gate electrode 518. As illustrated, the trenches 522a, 522b, 522c may extend in part through the dielectric material 107, and the dielectric material 107 may act as etch stop layer to stop the etch process. In some examples of method 400, the trenches 522a, 522b, 522c may extend completely through the dielectric material 107, such as shown in FIG. 2. Also at 424, the masks 520 may be removed after the trench formation process.

Referring again to FIG. 4, the method 400 then proceeds from 424 to 428, where the trenches 522a, 522b, 522c are filled with dielectric material 124, to respectively form the gate cuts 122a, 122b, 122c, as illustrated in FIG. 5J. According to some embodiments, a top surface of the dielectric material 124 may be polished using, for example, chemical mechanical polishing (CMP). The top surface of dielectric material 124 may be polished until it is substantially planar with a top surface of the gate electrodes 118a, 118b, 118c, 118d. As described above, gate cuts 122a, 122b, 122c may include one or more layers or bodies of dielectric material, such as the example case of one or more dielectric liner layers generally defining the gate cut perimeter, and one or more additional layers to fill the gate cut recess. In some cases, the gate cuts 122a, 122b, 122c may include one or more air gaps.

The resultant structure of FIG. 5J is similar to the structure 100 of FIG. 1A. Note that similar to FIG. 1A, the structure 100 of FIG. 5J has the substrate 102. In an example, the substrate 102 can optionally be at least partially, or completely removed, as discussed with respect to FIG. 3 above and described below with respect to FIG. 5J.

Referring again to FIG. 4, the method 400 then proceeds from 428 to 432, where from the backside, the substrate 102 may be planarized and polished, to at least in part remove the substrate 102, as illustrated in FIG. 5K. As discussed, the process 432 may be optional, e.g., if it is desired to remove the substrate 102. For example, the integrated circuit chip is flipped upside down (although the flipping is not illustrated in FIG. 5K, and the integrated circuit chip is shown in its original orientation), and the backside of the integrated circuit chip is processed from the top. Polishing the substrate 102 may reduce the height of the substrate, and in one example, may remove the substrate, as illustrate in FIG. 5K. As described above with respect to FIG. 3, removal of the substrate 102 facilitates in forming backside contacts for the source, drain, and/or gate structures, and/or in forming backside interconnect feature for backside signal and/or power routing, although such contacts and interconnect features are not illustrated in FIG. 3.

Referring again to the method 400 of FIG. 4, the method 400 proceeds from 432 to 440. At 440, a general integrated circuit (IC) is completed, as desired, in accordance with some embodiments. Such additional processing to complete an IC may include formation of conductive gate, source and/or drain contacts, back-end or back-end-of-line (BEOL) processing to form one or more metallization layers and/or to interconnect the transistor devices formed, for example. Any other suitable processing may be performed, as will be apparent in light of this disclosure.

Note that the processes in method 400 are shown in a particular order for ease of description. However, one or more of the processes may be performed in a different order or may not be performed at all (and thus be optional), in accordance with some embodiments. Numerous variations on method 400 and the techniques described herein will be apparent in light of this disclosure.

Example System

FIG. 5 illustrates a computing system 1000 implemented with integrated circuit structures formed using the techniques disclosed herein, in accordance with some embodiments of the present disclosure. As can be seen, the computing system 1000 houses a motherboard 1002. The motherboard 1002 may include a number of components, including, but not limited to, a processor 1004 and at least one communication chip 1006, each of which can be physically and electrically coupled to the motherboard 1002, or otherwise integrated therein. As will be appreciated, the motherboard 1002 may be, for example, any printed circuit board, whether a main board, a daughterboard mounted on a main board, or the only board of system 1000, etc.

Depending on its applications, computing system 1000 may include one or more other components that may or may not be physically and electrically coupled to the motherboard 1002. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1000 may include one or more integrated circuit structures or devices formed using the disclosed techniques in accordance with an example embodiment. In some embodiments, multiple functions can be integrated into one or more chips (e.g., for instance, note that the communication chip 1006 can be part of or otherwise integrated into the processor 1004).

The communication chip 1006 enables wireless communications for the transfer of data to and from the computing system 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1000 may include a plurality of communication chips 1006. For instance, a first communication chip 1006 may be dedicated to shorter range wireless communications such as Wi-Fi and Bluetooth and a second communication chip 1006 may be dedicated to longer range wireless communications such as GPS, EDGE, GPRS, CDMA, WiMAX, LTE, Ev-DO, and others.

The processor 1004 of the computing system 1000 includes an integrated circuit die packaged within the processor 1004. In some embodiments, the integrated circuit die of the processor includes onboard circuitry that is implemented with one or more integrated circuit structures or devices formed using the disclosed techniques, as variously described herein. The term “processor” may refer to any device or portion of a device that processes, for instance, electronic data from registers and/or memory to transform that electronic data into other electronic data that may be stored in registers and/or memory.

The communication chip 1006 also may include an integrated circuit die packaged within the communication chip 1006. In accordance with some such example embodiments, the integrated circuit die of the communication chip includes one or more integrated circuit structures or devices formed using the disclosed techniques as variously described herein. As will be appreciated in light of this disclosure, note that multi-standard wireless capability may be integrated directly into the processor 1004 (e.g., where functionality of any chips 1006 is integrated into processor 1004, rather than having separate communication chips). Further note that processor 1004 may be a chip set having such wireless capability. In short, any number of processor 1004 and/or communication chips 1006 can be used. Likewise, any one chip or chip set can have multiple functions integrated therein.

In various implementations, the computing system 1000 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device or system that processes data or employs one or more integrated circuit structures or devices formed using the disclosed techniques, as variously described herein. Note that reference to a computing system is intended to include computing devices, apparatuses, and other structures configured for computing or processing information.

### FURTHER EXAMPLE EMBODIMENTS

The following examples pertain to further embodiments, from which numerous permutations and configurations will be apparent.

Example 1. An integrated circuit comprising: a first semiconductor device comprising (i) a first source region, (ii) a first drain region, (iii) a first body comprising semiconductor material extending in a first direction from the first source region to the first drain region, (iv) a first sub-fin below the first body, and (v) a first gate structure extending in a second direction and on the first body; a second semiconductor device comprising (i) a second source region, (ii) a second drain region, (iii) a second body comprising semiconductor material extending in the first direction from the second source region to the second drain region, (iv) a second sub-fin below the second body, and (v) a second gate structure extending in the second direction and on the second body; a gate cut laterally between and separating the first gate structure and the second gate structure, the gate cut comprising a first dielectric material; a second dielectric material that is laterally between the first and second sub-fins, and a third dielectric material that is (i) laterally between the first and second sub-fins and (i) above the second dielectric material; wherein the gate cut is above the third dielectric material.

Example 2. The integrated circuit of example 1, wherein an interface is between the second dielectric material and the third dielectric material.

Example 3. The integrated circuit of example 2, wherein the interface is a seam or a grain boundary.

Example 4. The integrated circuit of any one of examples 1-3, wherein the second dielectric material and the third dielectric material are compositionally different.

Example 5. The integrated circuit of any one of examples 1-4, wherein the second dielectric material and the third dielectric material are elementally the same.

Example 6. The integrated circuit of any one of examples 1-5, wherein the gate cut extends within, but not through, the third dielectric material.

Example 7. The integrated circuit of any one of examples 1-6, wherein the gate cut is not in contact with the second dielectric material.

Example 8. The integrated circuit of any one of examples 1-5, wherein the gate cut extends through the third dielectric material, and is in contact with the second dielectric material.

Example 9. The integrated circuit of any one of examples 1-8, wherein the third dielectric material comprises silicon and one or more of oxygen, nitrogen, or carbon.

Example 10. The integrated circuit of any one of examples 1-10, wherein the second dielectric material comprises silicon and one or more of oxygen, nitrogen, or carbon.

Example 11. The integrated circuit of any one of examples 1-10, wherein the third dielectric material is an etch stop layer.

Example 12. The integrated circuit of any one of examples 1-11, further comprising a substrate that is below the sub-fin and below the third dielectric material.

Example 13. The integrated circuit of any one of examples 1-12, wherein the second dielectric material has a first height and the third dielectric material has a second heights, the first and second heights measured in a vertical direction orthogonal to both the first and second directions, wherein the first height is greater than the second height by at least 10%.

Example 14. The integrated circuit of any one of examples 1-13, wherein the first gate structure wraps around at least a section of the first body, and the first body is one of a nanoribbon, a nanosheet, or a nanowire.

Example 15. The integrated circuit of any one of examples 1-13, wherein the first gate structure in part wraps around at least a section of the first body, and the first body is a fin.

Example 16. The integrated circuit of any one of examples 1-14, further comprising: a vertical stack of a plurality of bodies comprising semiconductor material extending in the first direction from the first source region to the first drain region, the plurality of bodies includes the first body, and the plurality of bodies comprises a plurality of nanoribbons, nanowires, or nanosheets.

Example 17. A printed circuit board comprising the integrated circuit of any one of examples 1-16.

Example 18. An integrated circuit comprising: a first sub-fin, and a first gate structure above the first sub-fin; a second sub-fin, and a second gate structure above the second sub-fin; a gate cut laterally between the first and second gate structures, the gate cut comprising a first dielectric material; a second dielectric material laterally between the first and second sub-fins; and an etch stop layer that is between the second dielectric material and the gate cut.

Example 19. The integrated circuit of example 18, wherein the etch stop layer comprises a third dielectric material, with an interface between the second dielectric material and the third dielectric material of the etch stop layer.

Example 20. The integrated circuit of any one of examples 18-19, wherein the etch stop layer is in contact with each of the first gate structure and the second gate structure.

Example 21. The integrated circuit of any one of examples 18-20, wherein the first gate structure comprises gate dielectric that is on at least a section of an upper surface of the etch stop layer, a gate electrode.

Example 22. The integrated circuit of any one of examples 18-21, further comprising: (i) a first source region, (ii) a first drain region, (iii) a first body comprising semiconductor material extending laterally from the first source region to the first drain region, the first body above the first sub-fin, wherein the first gate structure is on the first body; and (i) a second source region, (ii) a second drain region, (iii) a second body comprising semiconductor material extending laterally from the second source region to the second drain region, the second body above the second sub-fin, wherein the second gate structure is on the second body.

Example 23. The integrated circuit of any one of examples 18-22, wherein each of the first body and the second body is one of a nanoribbon, a nanosheet, a nanowire, or a fin.

Example 24. An integrated circuit comprising: a first sub-fin, and a first gate structure above the first sub-fin; a second sub-fin, and a second gate structure above the second sub-fin; a structure laterally between and separating the first and second gate structures, the structure comprising a first dielectric material; a second dielectric material laterally between the first and second sub-fins, the structure landing on the second dielectric material; and a backside interconnect structure comprising a third dielectric material and that is below the first and second sub-fins; wherein the second dielectric material is compositionally distinct from the first dielectric material and the third dielectric material.

Example 25. The integrated circuit of example 24, wherein the structure extends within, but not through, the second dielectric material.

Example 26. The integrated circuit of any one of examples 24-25, wherein an interface extends laterally between a top surface of the backside interconnect structure and both (i) bottom surfaces of the first and second sub-fins and (ii) a bottom surface of the second dielectric material.

Example 27. The integrated circuit of any one of examples 24-25, further comprising: a fourth dielectric material that is (i) laterally between the first and second sub-fins, (i) below the second dielectric material, and (iii) above the backside interconnect structure, wherein the second dielectric material is compositionally distinct from the fourth dielectric material.

The foregoing description of example embodiments of the present disclosure has been presented for the purposes of illustration and description. It is not intended to be exhaustive or to limit the present disclosure to the precise forms disclosed. Many modifications and variations are possible in light of this disclosure. It is intended that the scope of the present disclosure be limited not by this detailed description, but rather by the claims appended hereto.

What is claimed is:

1. An integrated circuit comprising:
a first semiconductor device comprising (i) a first source region, (ii) a first drain region, (iii) a first body comprising semiconductor material extending in a first direction from the first source region to the first drain region, (iv) a first sub-fin below the first body, and (v) a first gate structure extending in a second direction and on the first body;
a second semiconductor device comprising (i) a second source region, (ii) a second drain region, (iii) a second body comprising semiconductor material extending in the first direction from the second source region to the second drain region, (iv) a second sub-fin below the second body, and (v) a second gate structure extending in the second direction and on the second body;
a gate cut laterally between and separating the first gate structure and the second gate structure, the gate cut comprising a first dielectric material;
a second dielectric material that is laterally between the first and second sub-fins, and a third dielectric material that is (i) laterally between the first and second sub-fins and (i) above the second dielectric material;
wherein the gate cut is above the third dielectric material.

2. The integrated circuit of claim 1, wherein an interface is between the second dielectric material and the third dielectric material.

3. The integrated circuit of claim 2, wherein the interface is a seam or a grain boundary.

4. The integrated circuit of claim 1, wherein the second dielectric material and the third dielectric material are compositionally different.

5. The integrated circuit of claim 1, wherein the second dielectric material and the third dielectric material are elementally the same.

6. The integrated circuit of claim 1, wherein the gate cut extends within, but not through, the third dielectric material.

7. The integrated circuit of claim 1, wherein the gate cut extends through the third dielectric material, and is in contact with the second dielectric material.

8. The integrated circuit of claim 1, wherein the third dielectric material comprises silicon and one or more of oxygen, nitrogen, or carbon.

9. The integrated circuit of claim 1, wherein the second dielectric material comprises silicon and one or more of oxygen, nitrogen, or carbon.

10. The integrated circuit of claim 1, further comprising a substrate that is below the sub-fin and below the third dielectric material.

11. The integrated circuit of claim 1, wherein the second dielectric material has a first height and the third dielectric material has a second heights, the first and second heights measured in a vertical direction orthogonal to both the first and second directions, wherein the first height is greater than the second height by at least 10%.

12. The integrated circuit of claim 1, wherein the first gate structure wraps at least in part around at least a section of the first body, and the first body is one of a nanoribbon, a nanosheet, a nanowire, or a fin.

13. The integrated circuit of claim 1, further comprising:
a vertical stack of a plurality of bodies comprising semiconductor material extending in the first direction from the first source region to the first drain region, the plurality of bodies includes the first body, and the plurality of bodies comprises a plurality of nanoribbons, nanowires, or nanosheets.

14. A printed circuit board comprising the integrated circuit of claim 1.

15. An integrated circuit comprising:
a first sub-fin, and a first gate structure above the first sub-fin;
a second sub-fin, and a second gate structure above the second sub-fin;
a gate cut laterally between the first and second gate structures, the gate cut comprising a first dielectric material;
a second dielectric material laterally between the first and second sub-fins; and
an etch stop layer that is between the second dielectric material and the gate cut.

16. The integrated circuit of claim 15, wherein the etch stop layer comprises a third dielectric material, with an interface between the second dielectric material and the third dielectric material of the etch stop layer.

17. The integrated circuit of claim 15, wherein the etch stop layer is in contact with each of the first gate structure and the second gate structure.

18. The integrated circuit of claim 15, wherein the first gate structure comprises gate dielectric that is on at least a section of an upper surface of the etch stop layer, a gate electrode.

19. An integrated circuit comprising:
a first sub-fin, and a first gate structure above the first sub-fin;
a second sub-fin, and a second gate structure above the second sub-fin;
a structure laterally between and separating the first and second gate structures, the structure comprising a first dielectric material;
a second dielectric material laterally between the first and second sub-fins, the structure landing on the second dielectric material; and
a backside interconnect structure comprising a third dielectric material and that is below the first and second sub-fins;
wherein the second dielectric material is compositionally distinct from the first dielectric material and the third dielectric material.

20. The integrated circuit of claim 19, wherein the structure extends within, but not through, the second dielectric material.

21. The integrated circuit of claim 19, wherein an interface extends laterally between a top surface of the backside interconnect structure and both (i) bottom surfaces of the first and second sub-fins and (ii) a bottom surface of the second dielectric material.

22. The integrated circuit of claim 19, further comprising:
a fourth dielectric material that is (i) laterally between the first and second sub-fins, (i) below the second dielectric material, and (iii) above the backside interconnect structure, wherein the second dielectric material is compositionally distinct from the fourth dielectric material.
